(19) United States
(12) Patent Application Publication
(10) Pub. No.: US 2004/0014314 A1
(43) Pub. Date: Jan. 22, 2004

(54) Evaporative deposition with enhanced film uniformity and stoichiometry

(76) Inventor: Joseph F. Brooks, Nampa, ID (US)

Correspondence Address: DICKSTEIN SHAPIRO MORIN & OSHINSKY LLP, 2101 L STREET NW, WASHINGTON, DC, 20037-1526, US

(21) Appl. No.: 10/128,349

(22) Filed: Apr. 24, 2002

(51) Int. Cl. H01L 21/44

(52) U.S. Cl. 438/679

(57) ABSTRACT

A method and apparatus for forming a thermally-evaporated bina [symbol] (or greater) thin film are disclosed in which the surface area of an evaporatio [symbol] container is effectively increased by using an inert medium added to source materials that are to form the binary (or greater) film. Using this method a [symbol] apparatus, films having better uniformity and stoichiometry are achievable.

### FIELD OF THE INVENTION

This invention relates to the field of deposition of thin fil [symbol] composed of multiple materials by thermal evaporation.

### BACKGROUND

Evaporative deposition techniques are extremely importan [symbol] the semiconductor industry where there is a necessity for highly uniform an [symbol] very thin films of various materials. In the semiconductor industry, evapora [symbol] deposition is useful in forming a material layer of a desired stoichiometry frc [symbol] plurality of different materials.

In thermal evaporation techniques, vapor particles can be generated in high vacuum by sublimation or vaporization of a material via a variety of heating sources and then condensed on a substrate. Heating sou [symbol] include resistive heating sources, lasers, and electron beam sources. Typical material source is placed in an evaporation crucible or boat and a heat sourc [symbol] such as resistive heating coils, applies thermal energy to the crucible or boat (indirect resistive heating) causing the material source to melt and vaporize. Upon contacting a cooler surface the vaporized material condenses and for [symbol] film.

Formation of a homogenous thin film having high unifor [symbol] and desired stoichiometry by thermal evaporation of a single material is a sir [symbol] procedure because a homogenous material source will have only a single bo [symbol] point, a single freezing point, and there is no opportunity for dissociation. Therefore, under appropriate conditions, a very thin film that is useful for v [symbol] purposes can be easily formed. However, when a binary (or tertiary or grea [symbol] film is desired, problems are presented because of the differing physical characteristics (e.g., melting and boiling points) of the multiple source mate [symbol] and the ever-present problem of dissociation. Often, when forming binary [symbol] by thermal evaporation for semiconductor industrial purposes, a material gradient is unintentionally formed in the thin film where the initial material deposited does not have the desired stoichiometry. This requires longer formation times to reach the desired or required stoichiometric levels and c [symbol] lead to films that are not as uniform as desired. Such problems increase and exaggerated as the physical characteristics of the different source materials become increasingly divergent.

### SUMMARY

This invention provides a method for improving the stoichiometric character of a thermal-vapor-deposited material layer formed materials having different physical (e.g., melting and boiling points) and chemical properties. An inert medium is added to the source materials with evaporation container (e.g., a crucible) that are to form a binary (or greater upon vaporization and condensation. By this method, films of increased uniformity and maintained stoichiometry are achievable.

These and other advantages and features of the invention [symbol] be more clearly understood from the following detailed description which is provided in conjunction with the accompanying drawings.

### BRIEF DESCRIPTION OF THE DRAWINGS

FIG. 1 is a cut-away illustration showing source material [symbol] prior art techniques;

FIG. 2 is a cut-away illustration of materials used for evaporative deposition of a thin film in accordance with an embodiment of [symbol] invention;

FIG. 3 is an illustration of a technique of thin film deposit in accordance with an embodiment of the invention;

FIG. 4 is an illustration of a thin film deposited by prior a [symbol] techniques;

FIG. 5 is an illustration of a thin film deposited in accord [symbol] with an embodiment of the invention; and

FIG. 6 is an illustration relating to an example of a thin fil [symbol] produced in accordance with an embodiment of the invention.

### DETAILED DESCRIPTION

The invention relates to thin films that are at least binary i [symbol] nature and their deposition by evaporative techniques. In the semiconduct [symbol] industry it is often important to maintain both the stoichiometry in thin fil [symbol] and as well as the uniformity of the films. Thermal evaporation is an inexpe [symbol] and commonly used method of forming such films. This invention utilizes; method of increasing the surface area of an evaporation container, preferabl [symbol] using an inert medium added to source materials held by the container that to form the binary (or greater) film. By this method, films of increased uniformity and maintained stoichiometry are achievable.

In the following detailed description, reference is made to various specific embodiments in which the invention may be practiced. The embodiments are described with sufficient detail to enable those skilled in t [symbol] to practice the invention, and it is to be understood that other embodiment may be employed, and that structural and electrical changes may be made without departing from the spirit or scope of the present invention.

The terms “substrate” and “wafer” can be used interchangeably in the following description and may include any foundatio [symbol] surface, but preferably a semiconductor-based structure. The structure sho [symbol] be understood to include silicon, silicon-on insulator (SOI), silicon-on-sapp [symbol] (SOS), doped and undoped semiconductors, epitaxial layers of silicon supp [symbol] by a base semiconductor foundation, and other semiconductor structures. [symbol] semiconductor need not be silicon-based. The semiconductor could be sili [symbol] germanium, germanium, or gallium arsenide. When reference is made to t [symbol] substrate in the following description, previous process steps may have been utilized to form regions or junctions in or over the base semiconductor or foundation.

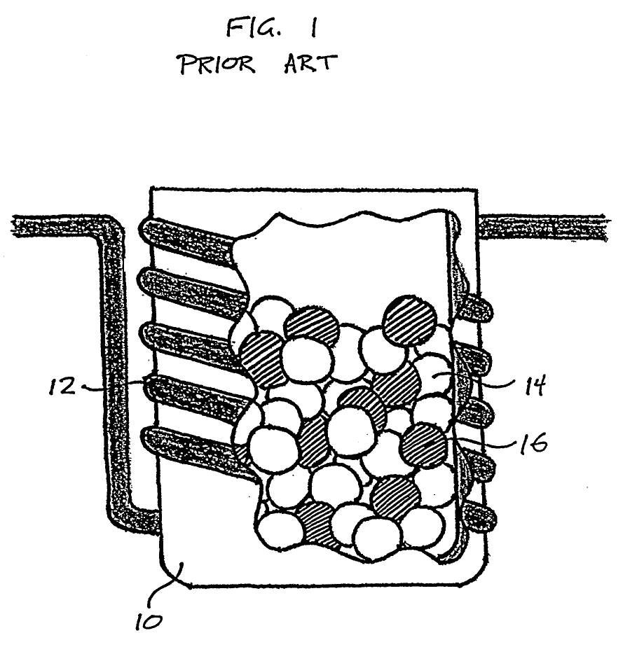

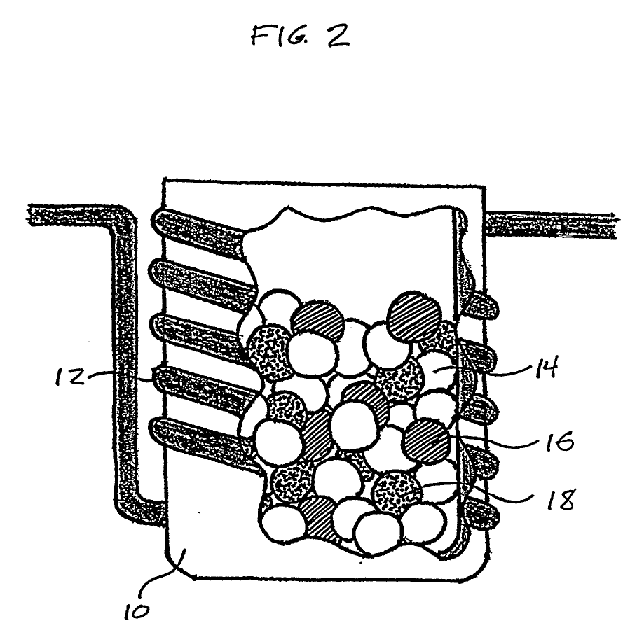

Now referring to the figures, where like reference number denote like features, FIG. 1 shows an example of how evaporative depositio [symbol] techniques in the prior art utilized source material. Prior art binary films w [symbol] produced by thermal evaporation by applying thermal energy to source: mat [symbol] until they vaporized and then condensed on the desired target (e.g., a semiconductor wafer). As is shown, to form a binary film, source materials comprising a first source material 14 and a second source material 16 are ad [symbol] to an evaporation container 10, such as a crucible or boat. These two sourc [symbol] materials 14 and 16, generally in the form of solid pellets shaped like marble [symbol] pebbles, are the two components that are desired to physically or chemical [symbol] combine to form the binary film. The source materials 14 and 16 can be in form of two sets of pellets, each respective set comprising one of the first or second source materials 14 and 16 as shown in FIGS. 1 and 2. Alternatively two source materials can be preliminarily combined in a desired stoichiome [symbol] form one set of pellets. As another alternative, the source materials 14 and can be in the form of a single solid entity comprising the entire mass of sou [symbol] material. In the prior art, the two source materials 14 and 16, once added [symbol] evaporation container 10, were subjected to thermal energy from a heat so [symbol] 12, typically a resistive heating coil, laser, or electron beam. Upon applicat [symbol] enough thermal energy, the materials 12 and 16 melt and then vaporize to the thin filn upon condensing. However, because the source materials 14 [symbol] 16 often have very divergent physical characteristics (e.g., melting and boili [symbol] points), one of the materials 14 typically melts and vaporizes, and subseque condenses on the target before the other of the source materials 16, leading undesirable film stoichiometric distribution and uniformity. These diverger [symbol] physical characteristics can also lead to dissociation (the separation of chemi [symbol] components into simpler fragments) during evaporation, also negatively impacting film quality.

In accordance with the invention, the problems associate [symbol] the prior art techniques can be mitigated, as shown in FIG. 2, by the additi [symbol] an inert medium 18 to the source materials 14 and 16 (be them in any of t [symbol] alternative forms) prior to the addition of thermal energy. The inert mediu [symbol] is preferably a material that has a high melting temperature (above that of e [symbol] source material 14 and 16), and is non-reactive in general, and particularly [symbol] the source materials 14 and 16. The inert medium 18, for instance, can be silicon or a ceramic based material.

Typically the inert medium 18 consists of solid material si [symbol] in shape and size to the source materials 14 and 16 (e.g., pellets); however, will be readily apparent to those of skill in the art that a multitude of variati [symbol] size and shape of the inert medium 18 are possible and, depending on the circumstances, desirable. Though the shape of the inert medium 18 can va [symbol] generally spherical shapes are preferred because such a design achieves the maximum relative surface area without interfering with the evaporation pro (because of folds, sharp corners, etc.). Further, the added inert medium 18 preferably large enough to effectively maximize evaporation container 10 su [symbol] area by contacting the container 10 itself, as well as the source materials 14 [symbol] 16. However, the size of the inert medium 18 should not be so large as to interfere with the evaporation process (e.g., by blocking the evaporation container 10 opening).

As shown in FIG. 2, the inert medium 18 is dispersed throughout the source material 14 and 16 within the evaporation container Preferably, enough inert medium 18 is added to the source materials 14 an [symbol] so that the thermal energy used for evaporation can be efficiently transferre [symbol] from the evaporation container 10 to the source materials 14 and 16 as equ [symbol] as possible.

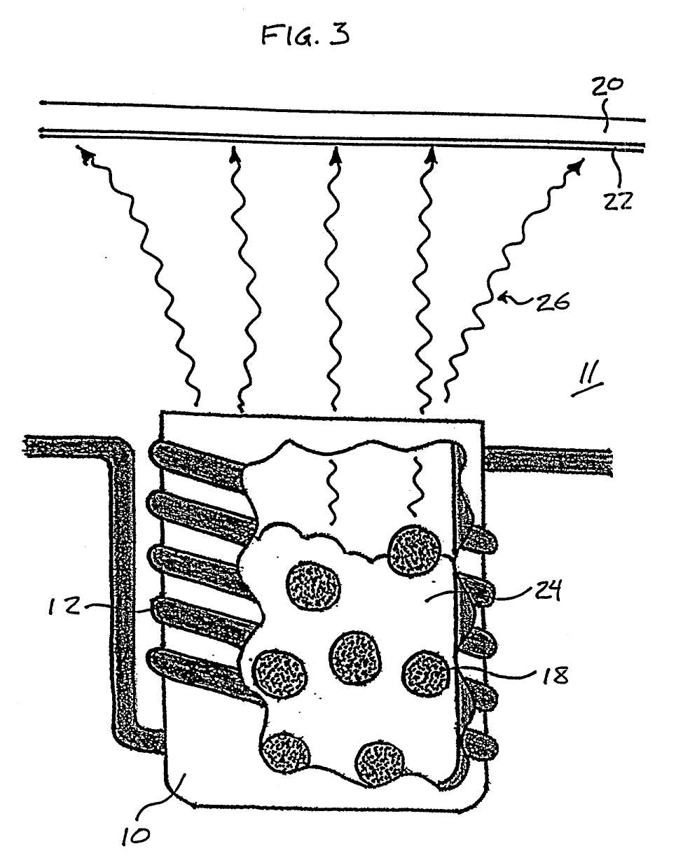

As shown in FIG. 3, The added inert medium 18 of the invention serves to increase the heating area during the evaporation process The addition of the inert medium 18 also reduces the amount of power nee [symbol] to melt the source material 14 and 16, even towards the middle of the evaporation container 10, which typically in the prior art required additiona [symbol] energy. When heat is applied by the heat source 12, preferably in a vacuum chamber 11, the source material 14 and 16 in the evaporation container me form a liquefied source material 24, which upon continued application of thermal energy becomes a vaporized source material 26. This vaporized so [symbol] material 26 condenses upon contacting the cooler wafer 20, which is positi [symbol] in proximity to the evaporation container (preferably within a vacuum evaporation chamber 11, positioned above and facing the source material). Upon condensing, the vaporized source material 26 forms a thin film 22 comprising a combination of source materials 14 and 16, desirably in the sa [symbol] stoichiometric ratio as initially present in the evaporation container. Typical film of about 25 Å to about 5 μm is desired as useful in the semiconductor industry, which can be produced using the invention.

The uneven heating, melting, and evaporation of the sour [symbol] materials 14 and 16 found in the prior art is diminished so that the two sou [symbol] materials 14 and 16 melt and vaporize more quickly and more synchronous [symbol] The result is that the resultant film deposits in less time, leading to more un [symbol] films, and has a more desirable stoichiometry due, in part, to less dissociatio

[symbol]

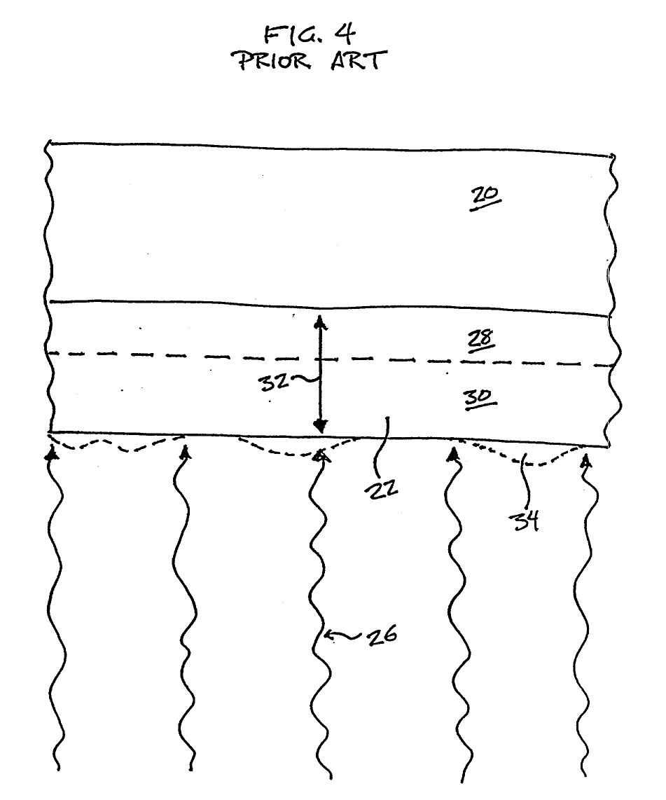

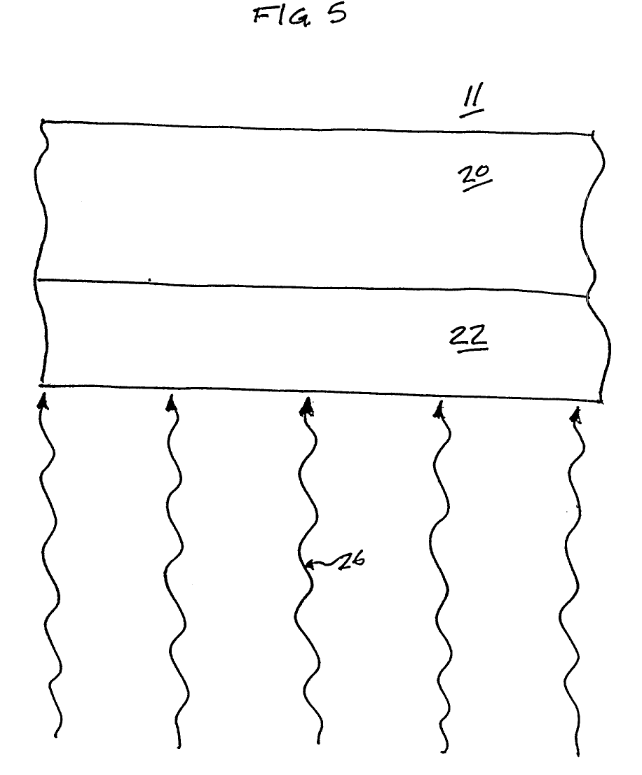

As illustrated in FIG. 4, because of the uneven heating, melting, evaporation, and dissociation of components found in the prior art first portion 28 of the thin film 22 was, in general, predominantly comprise [symbol] whichever of the source materials 14 and 16 has the lowest melting and boil points, wherein the second portion 30 of the thin film 22 has closer to the desired stoichiometry, being deposited once the second of the source mater [symbol] 14 and 16 reaches its boiling point. It is also possible that under the circumstances of the prior art that the outermost portion of the thin film 22 would have an undesirably high amount of the second source material 14 o [symbol] to vaporize, which would continue to be deposited even after the first sourc [symbol] material is exhausted. Thus, a gradient 32 would be created in the thin film [symbol] where the proportional amounts of source material 14 and 16 shifts from o [symbol] extreme to the other through the thickness of the film 22. Additionally, un [symbol] such circumstances, an uneven surface 34 could develop on the thin film 22 shown in FIG. 5, when compared to the thin film 22 of the prior art, the invention can achieve a thinner, more uniform thin film 22 of a more consis [symbol] desired stoichiometry.

Though this invention has been described primarily with reference to binary films utilizing two source materials 14 and 16, it can als [symbol] achieve thin films 22 of desired uniformity and stoichiometry utilizing three more source materials.

### EXAMPLE

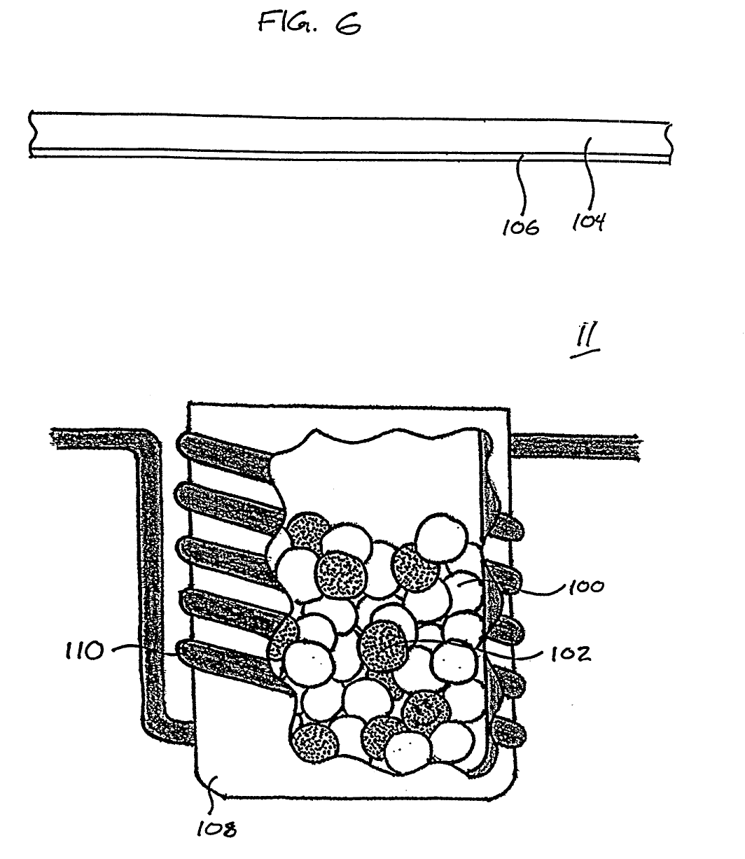

The following supporting data was obtained in experiment [symbol] using actual embodiments of the invention. Table I below shows experime [symbol] results. The experiments are explained in reference to FIG. 6.

TABLE I

| | Inert | Source | Power | Film Silver | Film Sele |
|---|---|---|---|---|---|
| | Medium | Material | (% maximum) | (mole %) | (mole %) |
| Control | None | Ag₂Se | 11% | 59.60 | 40.4 |
| | added | | | | |
| Run 1 | Si added | Ag₂Se | 13% | 64.80 | 35.2 |
| Run 2 | Si added | Ag₂Se | 16% | 68.90 | 31.1 |

Each experimental run was conducted in a vacuum chamb and used a standard ceramic crucible 108 as an evaporation container 10 an [symbol] standard resistive heating coils 110 for a heat source 12, as is known in the [symbol] As a deposition target, a 3500 Å layer of TEOS oxide over a 200 mm silico [symbol] wafer having a (111) crystalline orientation served as a substrate 104 upon [symbol] to condense the thin film. The source material used in all runs were pellets formed of silver and selenium (Ag₂Se), manufactured on site to be of know [symbol] stoichiometry. The target stoichiometry for the deposited thin films was Ag₆₆Se₃₃ and the initial stoichiometry of the source material reflected this de [symbol] film stoichiometry in a 2:1 ratio (with Ag being no greater than 2). For eac [symbol] run, thermal energy was applied to the crucible 108 and its contents by the resistive heating coils 110 as a function of the % total power. The Ag₂Se so [symbol] pellets 100 were heated for a minimum of 60 seconds to vaporize. Time to boiling was subjective and a function of the % power used. The desired thi [symbol] for each deposited experimental film was 500 Å.

For the Control Run (reflecting prior art techniques), no medium was added to the Ag₂Se source pellets 100. The power used was a [symbol] 11% of total power. As is shown in Table I, the resulting stoichiometry of t [symbol] deposited film did not achieve the target 2:1 Ag to Se ratio, but the resultin [symbol] ratio did reflect results common to techniques used in the prior art. The undesired stoichiometry was due to the dissimilar physical characteristics of silver and selenium, uneven heating, and dissociation, resulting in uneven deposition rates and amounts between the source materials.

As shown in Table 1, Run 1 utilized the same Ag₂Se sour [symbol] pellets 100, but inert silicon (Si) media 102 was added in accordance with t [symbol] invention. Thermal energy was applied by the resistive heating coils at abo [symbol] 13% total power. The 500 Å film was deposited and determined by su [symbol] analysis to have close to target stoichiometry. Run 2 also utilized inert [symbol] (Si) media 102 in accordance with the invention. For Run 2, thermal e [symbol] was applied at about 16% total power. The resulting film was not as do target stoichiometry as with Run 1, but was still closer than the Control which used no inert media.

The above description, examples, and accompanying d [symbol] are only illustrative of exemplary embodiments, which can achieve the fe [symbol] and advantages of the present invention. It is not intended that the inve [symbol] limited to the embodiments shown and described in detail herein. The invention can be modified to incorporate any number of variations, alter [symbol] substitutions or equivalent arrangements not heretofore described, but w [symbol] commensurate with the spirit and scope of the invention. Accordingly, t [symbol] invention is not to be considered as being limited by the foregoing descri [symbol] but is only limited by the scope of the appended claims.

What is claimed as new and desired to be protected by Letters Pa [symbol] of the United States is:

1. A method of forming a film, comprising:
providing a source material comprising at least two components;
providing an inert medium interspersed throughout said source mate [symbol] heating said source material to evaporate at least a portion of said so [symbol] material; and
condensing said evaporated source material on a surface.

2. The method of claim 1, wherein said at least two components of said source material have an original stoichiometry that is at least approximately maintained throughout said film.

3. The method of claim 1, said source material comprises a plurality of masses, each of said plurality of masses comprising said at least t [symbol] components of said source material.

4. The method of claim 1, wherein each of said inert medium and said least two components of said source material have respective mel [symbol] points such that said inert medium has a melting point above tha [symbol] the components of said source material.

5. The method of claim 1, wherein said inert medium is silicon-based.

6. The method of claim 1, wherein said inert medium is ceramic-based.

7. The method of claim 1, wherein said heating is achieved by a resistiv [symbol] heating coil.

8. The method of claim 1, wherein said surface is a surface of a semiconductor wafer.

9. The method of claim 1, wherein said source material comprises silver selenium.

10. The method of claim 1, wherein said source material is Ag₂Se.

11. The method of claim 10, wherein said film comprises about 65 mole silver and about 35 mole % selenium.

12. The method of claim 10, wherein said film comprises about 66 mole silver and about 33 mole % selenium.

13. The method of claim 1, wherein said acts of heating, evaporating an [symbol] condensing occur in a vacuum chamber.

14. A method of forming a film, said method comprising:
providing a container;
providing a first source material and a second source material within container;
providing an inert medium within said container; and
applying thermal energy to said container, thereby causing the evaporation of said first and said second source materials, but no [symbol] said inert medium.

15. The method of claim 14, wherein said first and second source mater [symbol] have an original stoichiometry which is approximately maintaine [symbol] said film.

16. The method of claim 14, wherein said inert medium dissipates said thermal energy within said container.

17. The method of claim 14, wherein said inert medium and said first a [symbol] second source materials each have a respective melting point, sai [symbol] inert medium having a melting point above that of said first and second source materials.

18. The method of claim 14, wherein said inert medium comprises silic

[symbol]

19. The method of claim 14, wherein said inert medium comprises a cer

[symbol]

20. The method of claim 14, wherein said act of applying thermal energ [symbol] achieved by an electric coil.

21. The method of claim 14, wherein said inert medium causes evaporat [symbol] of said first and second source materials to occur approximately contemporaneously.

22. The method of claim 14, further comprising condensing said first an [symbol] second source materials onto a semiconductor wafer upon which film is formed.

23. The method of claim 14, wherein said first source material is silver a [symbol] said second source material is selenium in a ratio of two to one, respectively.

24. The method of claim 23, wherein said film comprises about 65 mole silver and about 35 mole % seleaum.

25. The method of claim 23, wherein said film comprises about 66 mole silver and about 33 mole % selenium.

26. The method of claim 14, wherein said evaporation occurs in a vacuu [symbol] chamber.

27. A method of forming a material layer on a semiconductor device, comprising:
providing a vacuum chamber comprising a resistive heating coil;
positioning a semiconductor wafer within said vacuum chamber;
positioning an evaporation container within said vacuum chamber an [symbol] contact with said resistive heating coil;
providing a plurality of source materials within said evaporation cont [symbol] said plurality of source materials comprising at least two material components;
providing an additive to said plurality of source materials within said evaporation container, said additive being non-reactive with said plurality of source materials;
vaporizing said plurality of source materials, without vaporizing said additive; and
condensing said plurality of source materials on a surface of said semiconductor wafer.

28. The method of claim 27, wherein said additive comprises silicon.

29. The method of claim 27, wherein said additive comprises a ceramic.

30. The method of claim 27, wherein said at least two components of sa [symbol] source materials within said evaporation container have an origin [symbol] stoichiometry that is approximately maintained throughout said material layer.

31. The method of claim 27, wherein said at least two components com [symbol] silver and selenium.

32. The method of claim 31, wherein said silver and selenium are presen [symbol] Ag₂Se.

33. The method of claim 32, wherein said metallization layer comprises 65 mole % silver and about 35 mole % selenium.

34. The method of claim 32, wherein said metallization layer comprises 66 mole % silver and about 33 mole % selenium.

35. An apparatus for physical deposition of a film by thermal evaporatio [symbol] comprising:
a vacuum chamber;
a container suitable to withstand temperatures in excess of a first temperature;
at least two source materials within said container, each of said at lea [symbol] two source materials having a boiling point up to said first temperature;
an inert medium within said container and interspersed among said [symbol] least two source materials, said inert medium having a melting po [symbol] in excess of said first temperature; and
a thermal energy generator capable of raising the temperature of sai [symbol] container, said at least two source materials, and said inert mediu [symbol] said first temperature.

36. The apparatus of claim 35, wherein said inert medium comprises sili

[symbol]

37. The apparatus of claim 35, wherein said inert medium comprises a ceramic.

38. The apparatus of claim 35, wherein said thermal energy generator comprises a resistive heating coil.

39. The apparatus of claim 35, wherein said at least two source materials comprise silver and selenium.

40. The apparatus of claim 35, wherein said silver and selenium are in th [symbol] form of Ag₂Se.
